(19) United States
(12) Patent Application Publication
(10) Pub. No.: US 2005/0076946 A1
(43) Pub. Date: Apr. 14, 2005

(54) Electricity-generating system and method and heat-resistant concrete and method for making such concrete

(76) Inventors: Rosario Michael Mannina, Antioch, IL (US); Gordon Head, Newport Richey, FL (US)

Correspondence Address: MICHAEL BEST & FRIEDRICH, LLP, 100 E WISCONSIN AVENUE, MILWAUKEE, WI, 53202, US

(21) Appl. No.: 10/489,513

(22) PCT Filed: Sep. 19, 2002
(86) PCT No.: PCT/US02/29788

Related U.S. Application Data
(60) Provisional application No. 60/323,301, filed on Sep. 19, 2001.

(51) Int. Cl. H01L 25/00

(52) U.S. Cl. 136/246

(57) ABSTRACT

Heat-resistant concrete, a method for making such concrete and an electricity-generating system and method using such concrete. The electricity-generating system may include a reservoir in which water is stored under pressure, a generator communicating with the reservoir and using the pressurized water to generate electricity to power the system, a solar field communicating with the generator and in which the water is pre-heated, an injection chamber communicating with the solar field and in which the pre-heated water is converted to super-heated steam, a parabolic dish solar array providing super-heated steam through pipes in the injection chamber to convert the pre-heated water to super-heated steam in the injection chamber, a series of steam generators, steam-booster substations communicating with the injection chamber and with the reservoir, the generators using the steam to generate electricity, the steam-booster substations maintaining the temperature and pressure of the steam as it flows through the generator series, the steam being fed from the series to the reservoir and condensed to re-enter the water supply, and a parabolic dish solar array feeding super-heated water through a manifold and through pipes in each booster substation. Heat-resistant concrete, preferably in the form of panels, is provided on the interior surface of the injection chamber and on the interior surface of the booster substations.

### CROSS REFERENCE TO RELATED APPLICATION

This application claims the benefit under 35 U.S.C. §119(e) of the filing date of U.S. Provisional Application Serial No. 60/323,301 filed on Sep. 19, 2001.

### FIELD OF THE INVENTION

The present invention relates to an electricity-generating system and method and, more particularly, heat-resistant concrete, a method for making such concrete and an electricity-generating system and method using such concrete.

### SUMMARY OF THE INVENTION

The present invention provides an electricity-generating system generally including a closed loop system using super-heated steam to generate electricity. Also, the present invention provides heat-resistant concrete and a method for making such concrete. In one embodiment, the heat-resistant concrete, preferably in the form of panels, is provided on the interior walls of the high-temperature, high-pressure structures in the electricity-generating system.

More particularly, the present invention provides an electricity-generating system including a reservoir in which water is stored under pressure and a generator communicating with the reservoir and using the pressurized water to generate electricity to power the system. The system also includes a solar field communicating with the generator and in which the water is pre-heated, an injection chamber communicating with the solar field and in which the pre-heated water is converted to super-heated steam, and a parabolic dish solar array providing super-heated steam through pipes in the injection chamber to convert the preheated water to super-heated steam in the injection chamber. In addition, the system includes a series of steam generators and steam-booster substations communicating with the injection chamber and with the reservoir, the generators using the steam to generate electricity, the steam-booster substations maintaining the temperature and pressure of the steam as it flows through the generator series, the steam being fed from the series to the reservoir and condensed to re-enter the water supply. Further, the system includes a parabolic dish solar array feeding super-heated water through a manifold and through pipes in each booster substation. Heat-resistant concrete, preferably in the form of panels, is provided on the interior surface of the injection chamber and on the interior surface of the booster substations.

Also, the present invention provides an injection chamber for use in an electricity-generating system, the system including a supply of water, a supply of super-heated water, and a steam generator using super-heated steam to generate electricity. The injection chamber includes a water chamber receiving water from the water supply and a steam chamber communicating with the water chamber and with the generator. The steam chamber includes pipes, preferably formed of titanium, carrying super-heated water from -the super-heated water supply. Water is supplied from the water chamber to the steam chamber and is converted to super-heated steam by the super-heated water flowing through the pipes. The super-heated steam is supplied to the generator to generate electricity. Heat-resistant concrete, preferably in the form of panels, is provided on the interior walls of the steam chamber.

In addition, the present invention provides a steam-booster substation for use in an electricity-generating system, the system including a supply of steam, a first generator and a second generator communicating with the steam supply and using the steam to generate electricity, and a supply of super-heated water. The substation includes a series of pipes, preferably formed of titanium, communicating with the super-heated water supply. The substation is positioned between the first and second generators, receives steam from the first generator, re-heats the steam using the super-heated water in the pipes, and feeds the re-heated steam to the second generator. Heat-resistant concrete, preferably in the form of panels, is provided on the interior walls of the substation.

Further, the present invention provides an electricity-generating method comprising the acts of storing water under pressure in a reservoir, feeding water through a generator to generate electricity to power the system, pre-heating water in a solar field, feeding pre-heated water to an injection chamber including a water chamber and a steam chamber, converting the pre-heated water to super-heated steam in the steam chamber including feeding pre-heated water from the water chamber and feeding super-heated water through pipes in the steam chamber, feeding super-heated steam to a first steam generator to generate electricity, re-heating the steam in a steam-booster substation including supplying the steam and super-heated water to the substation, generating electricity in a second steam generator using re-heated steam from the substation, and condensing the steam to water in the reservoir.

In addition, the present invention provides a heat-resistant concrete comprising cement and a detergent. More particularly, the heat-resistant concrete comprises cement, a detergent, silica sand, fine silica sand, hardener and baking soda.

Furthermore, the present invention provides a method of preparing a heat-resistant concrete. The method comprises the acts of mixing fine silica sand with a hardener to form a mixture, and then adding silica sand, cement and baking soda to the mixture. All of these components are then slowly mixed with one another. Liquid detergent is then added to the mixture to form the heat-resistant concrete.

Independent features and independent advantages of the present invention will become apparent to those skilled in the art upon review of the following detailed description and drawings.

### BRIEF DESCRIPTION OF THE DRAWINGS

FIGS. 14 are diagrams of alternative constructions of an electricity-generating system embodying the present invention.

FIG. 5 is a diagram of a portion of the system shown in FIGS. 1-4.

FIGS. 6-11 are views of the reservoir building shown in FIGS. 1-4.

FIG. 12 are views of the hydroelectric generators shown in FIGS. 1-4.

FIG. 13 is a diagram of a portion of the system shown in FIGS. 1-4.

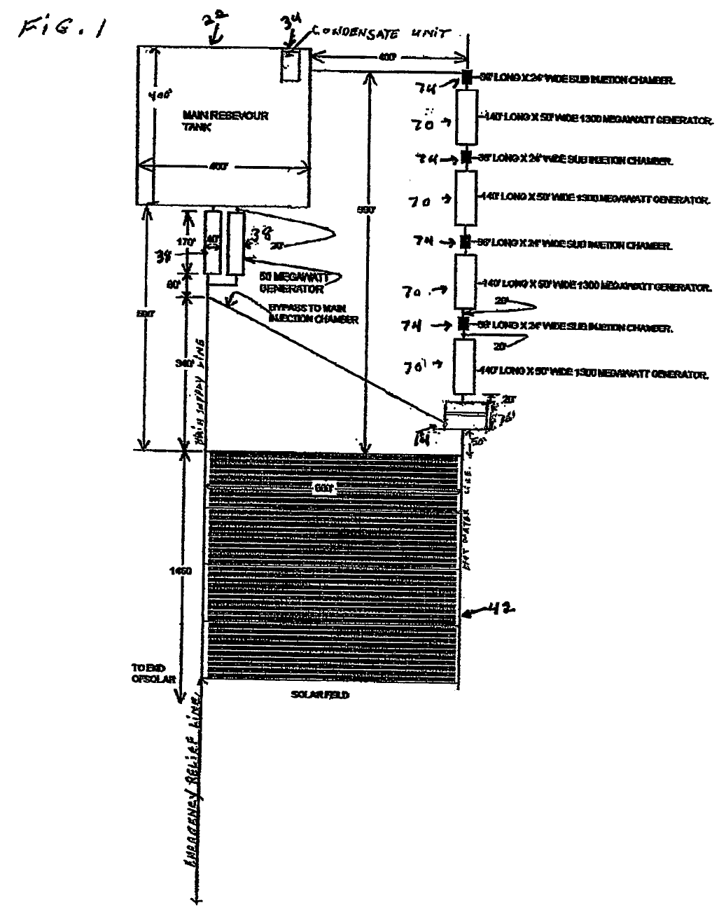

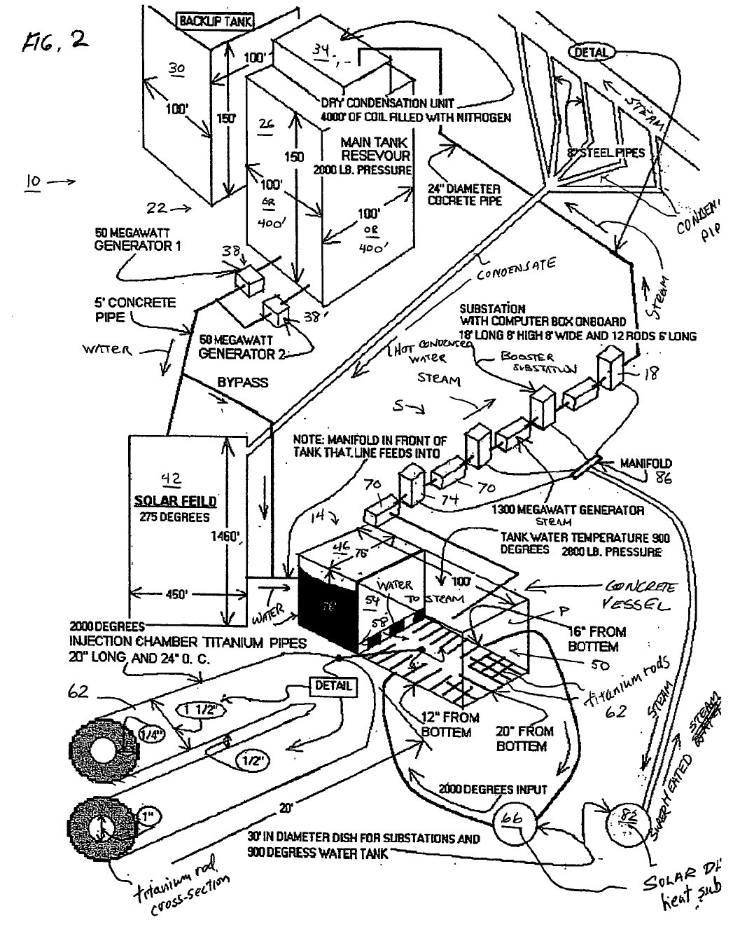

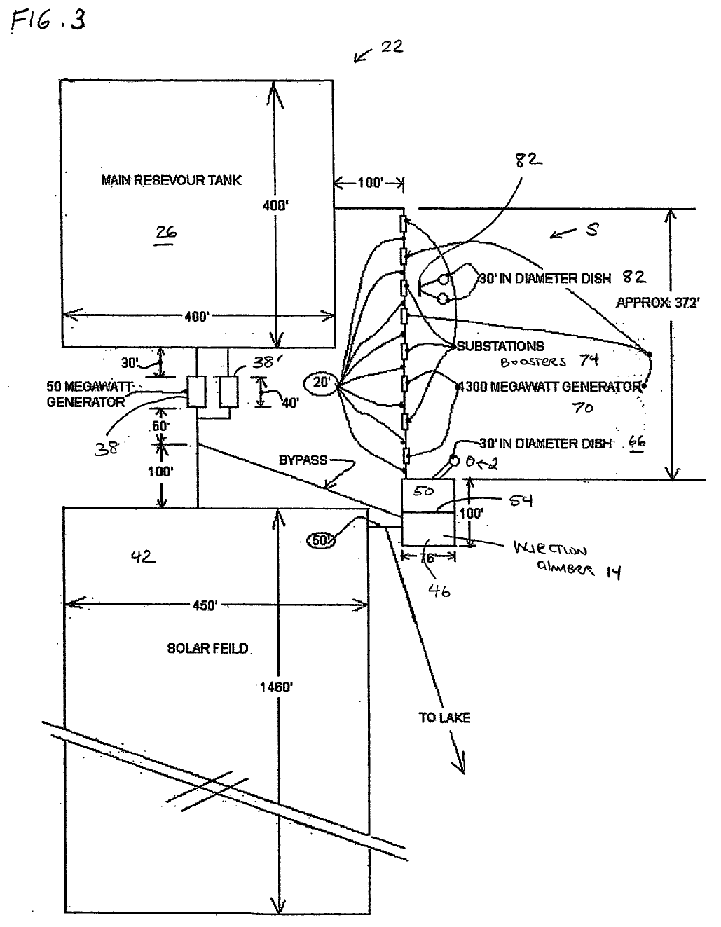

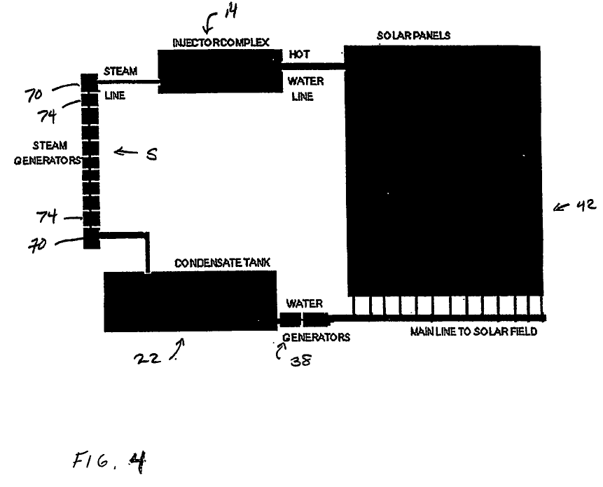

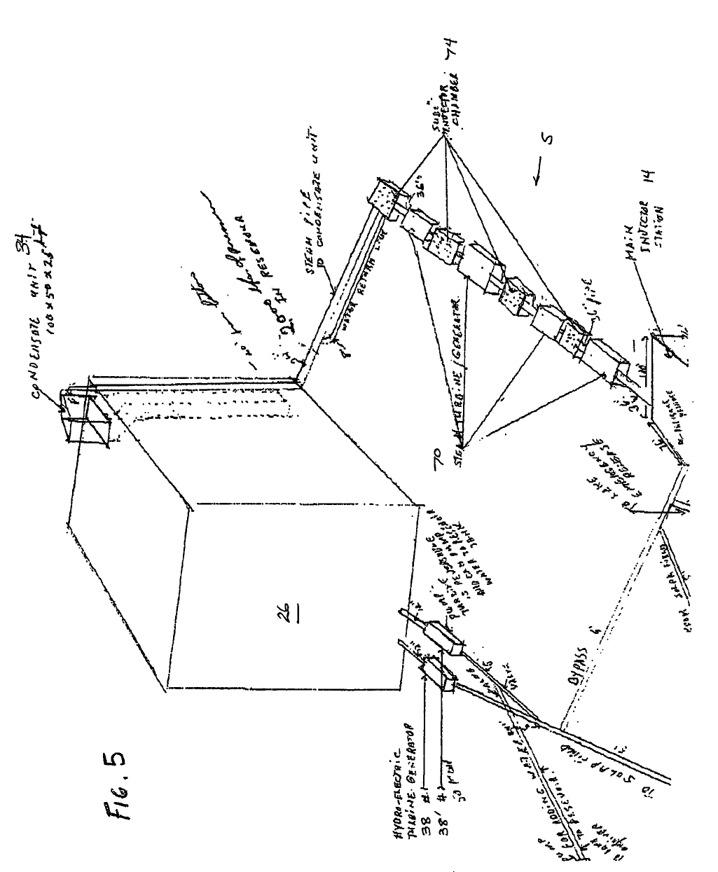

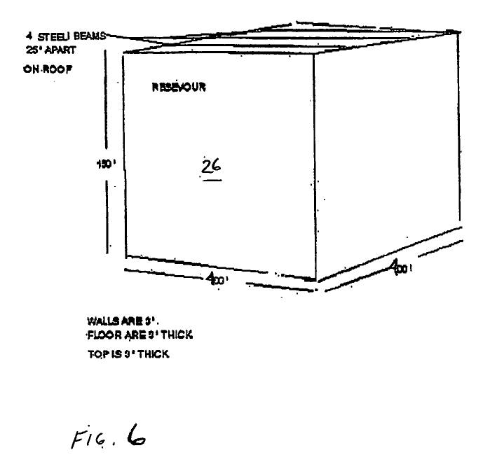

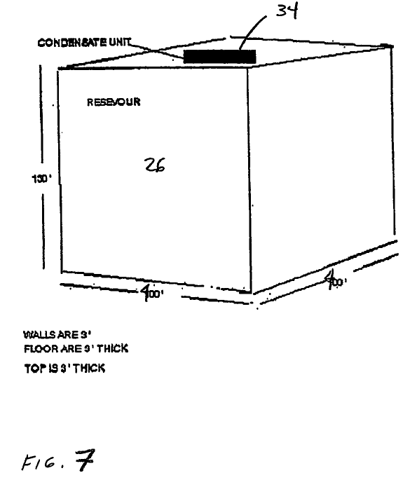

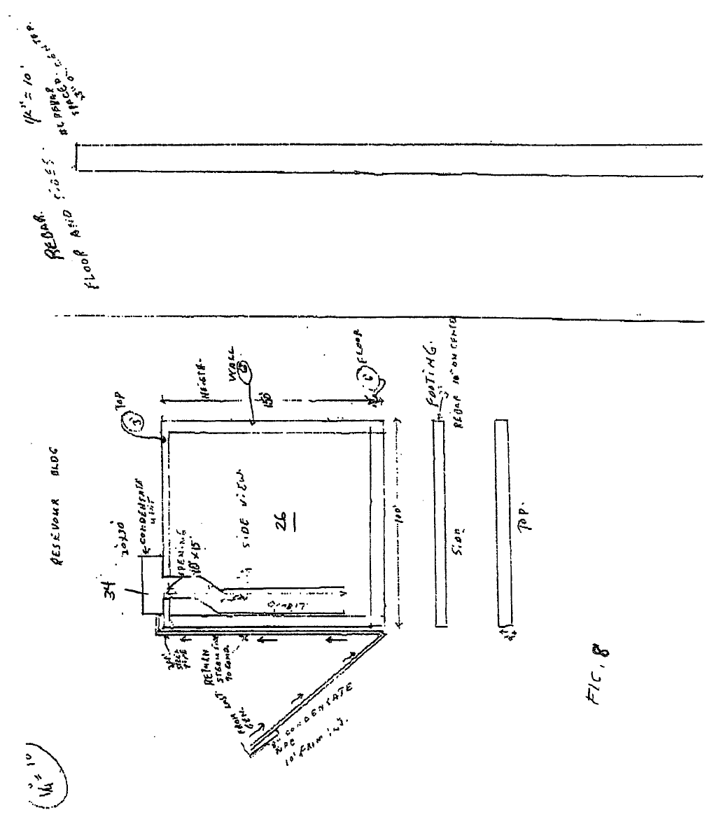

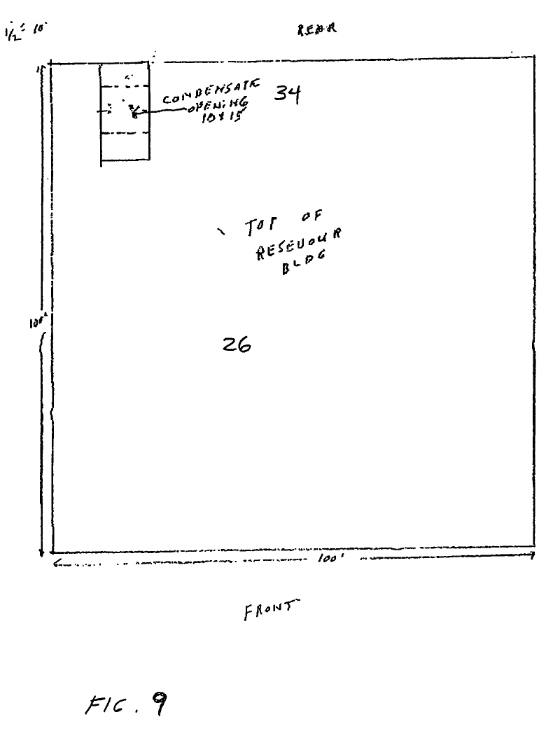

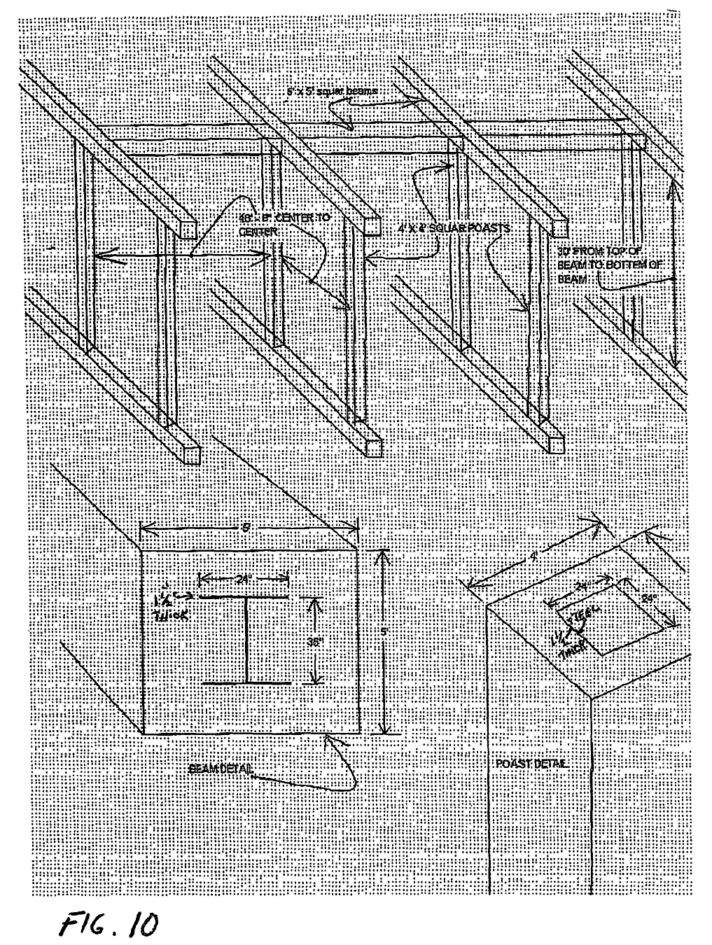

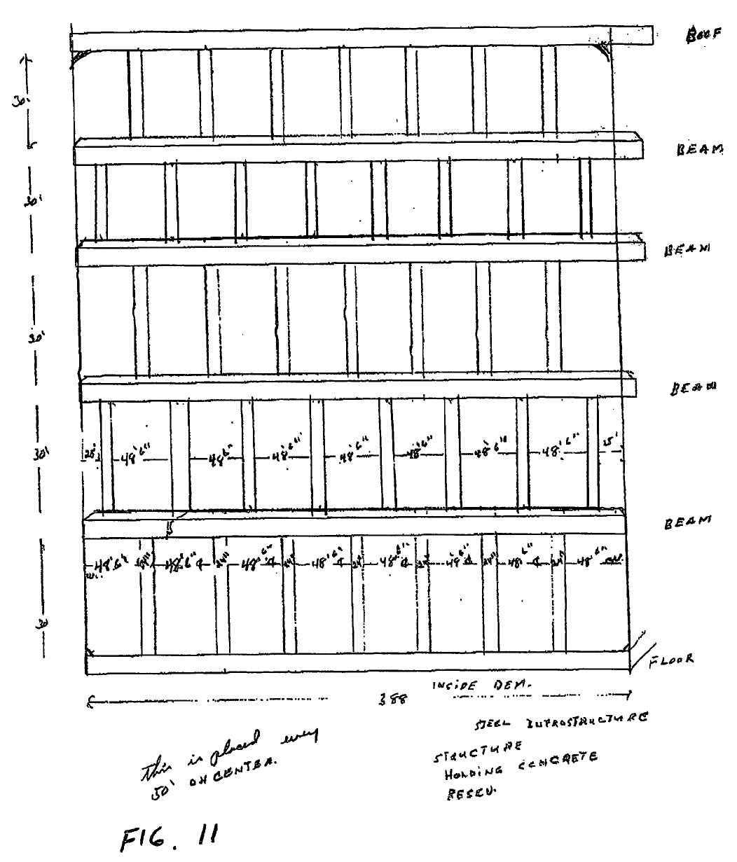

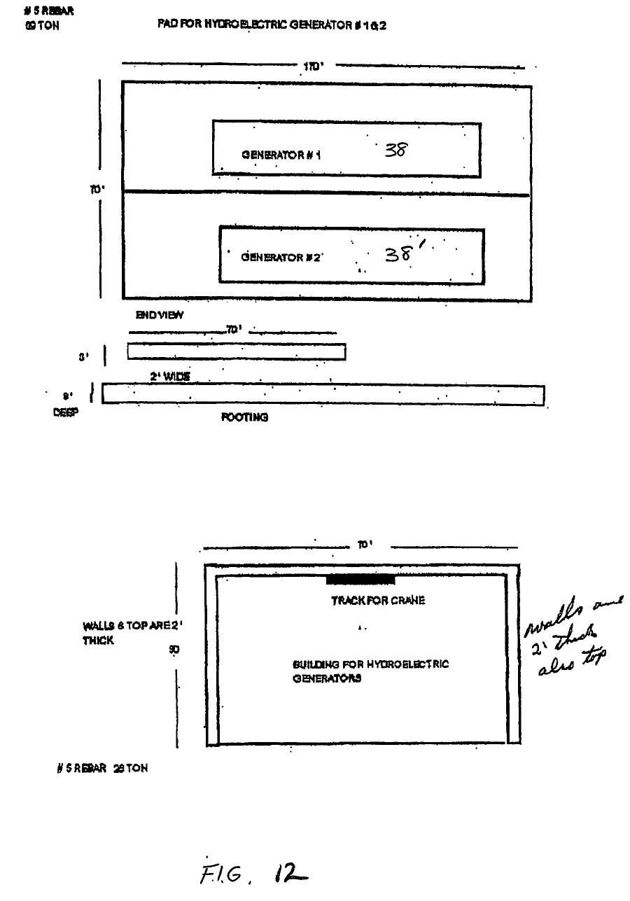

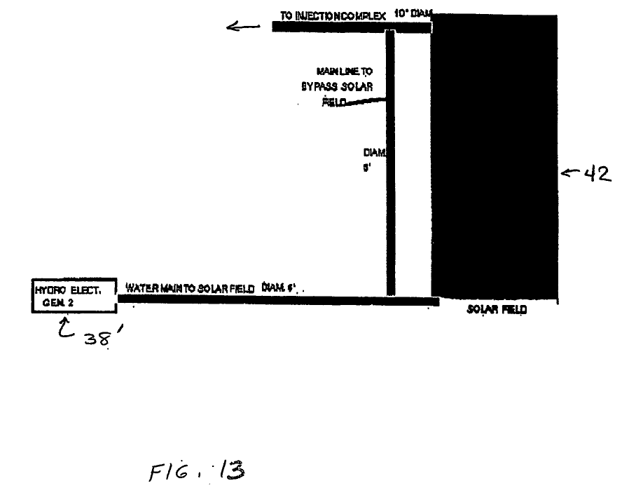

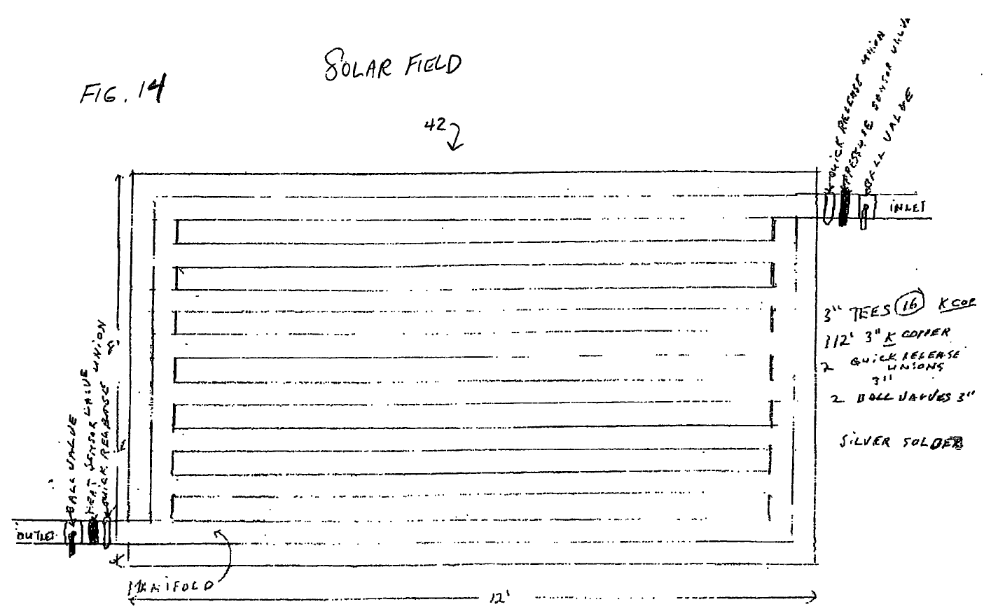

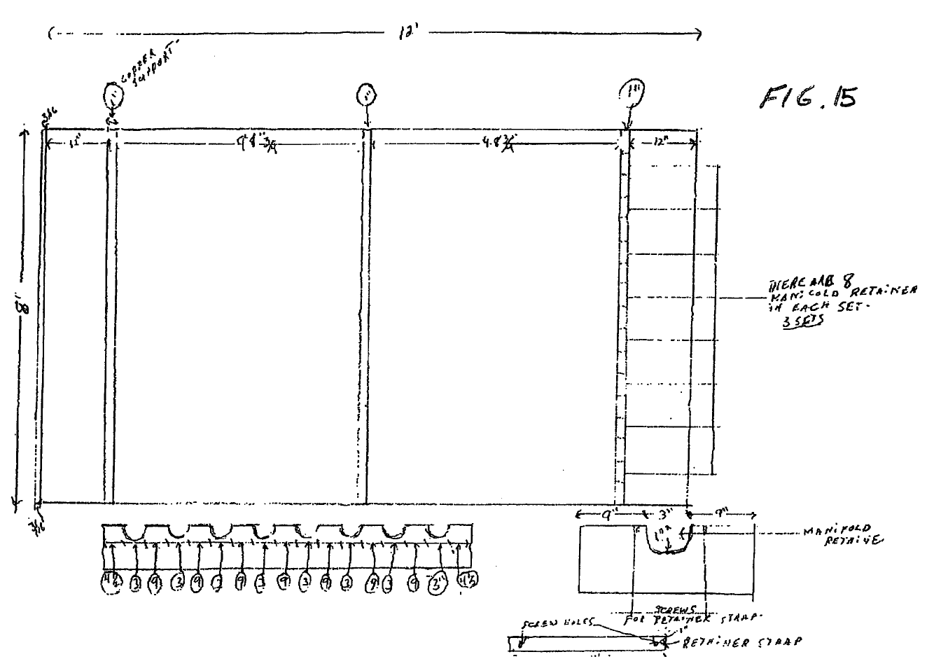

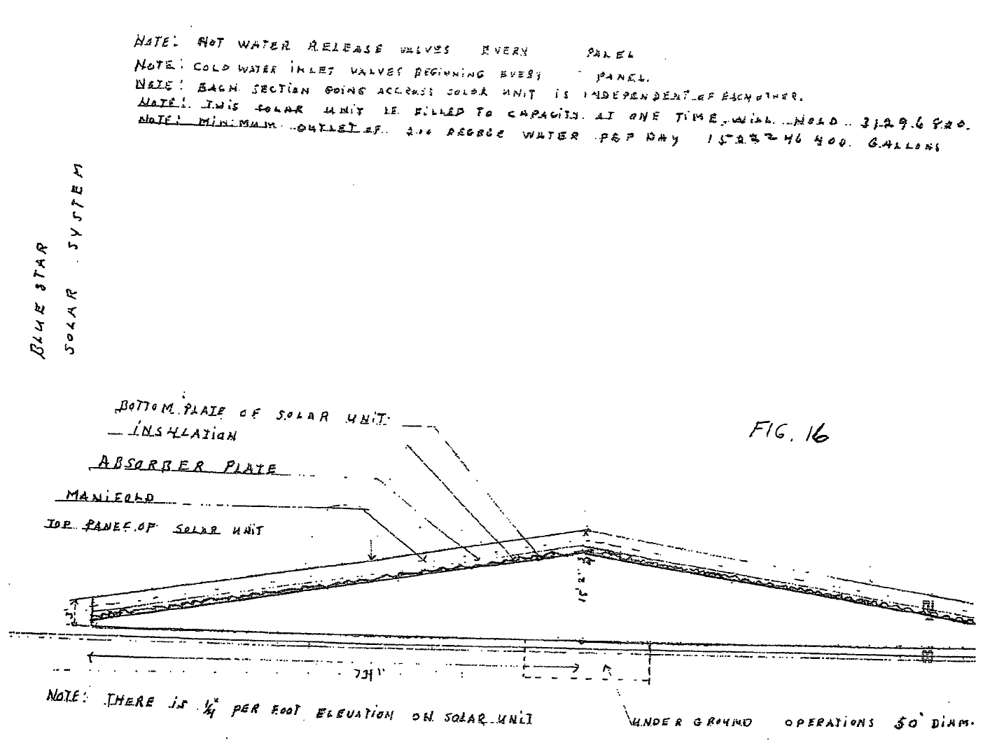

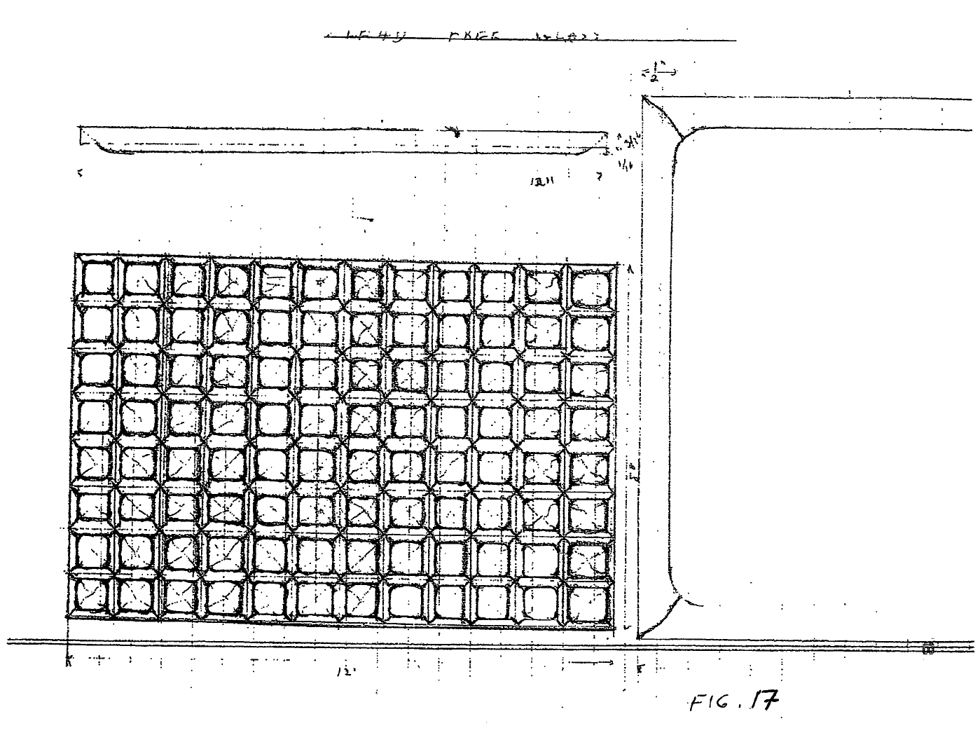

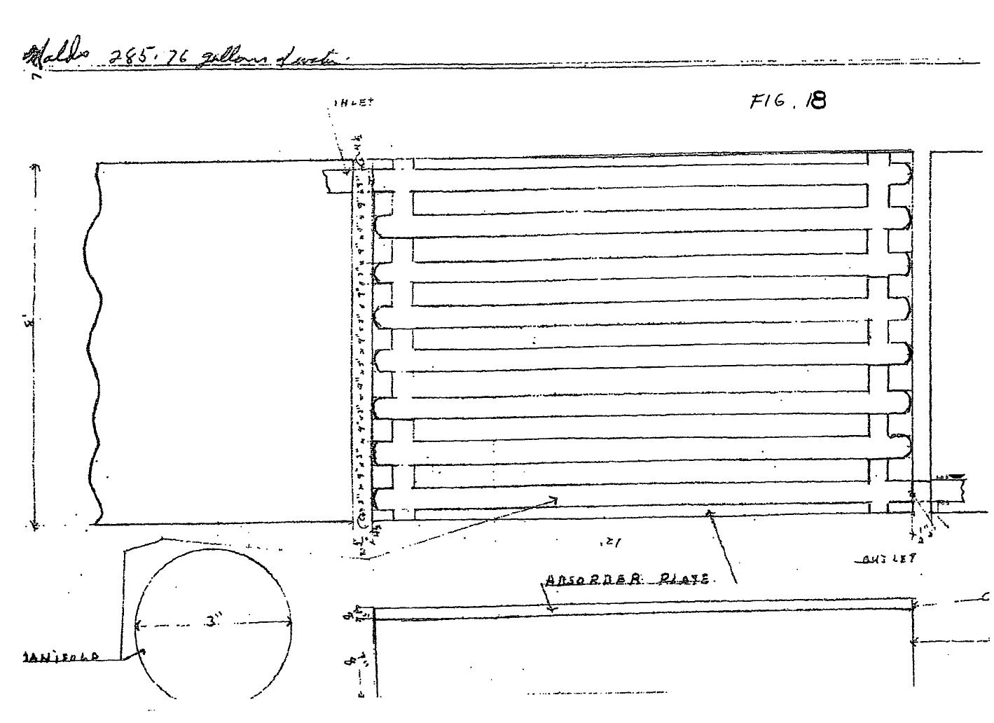

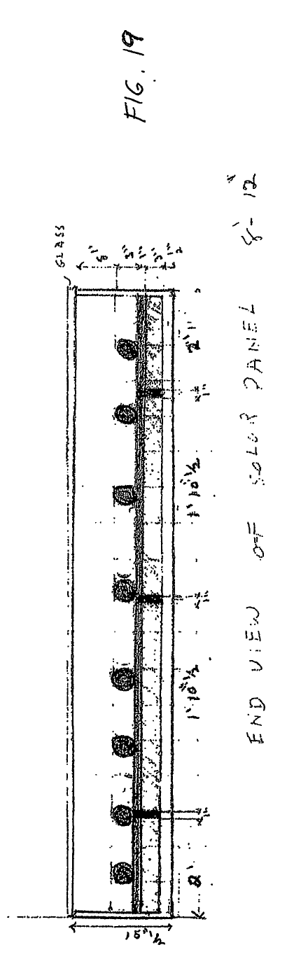

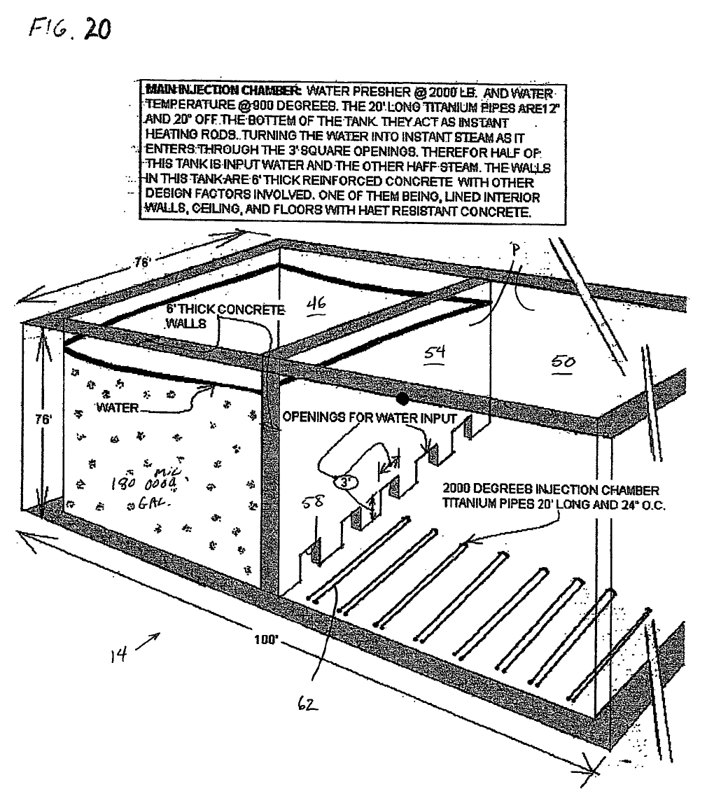

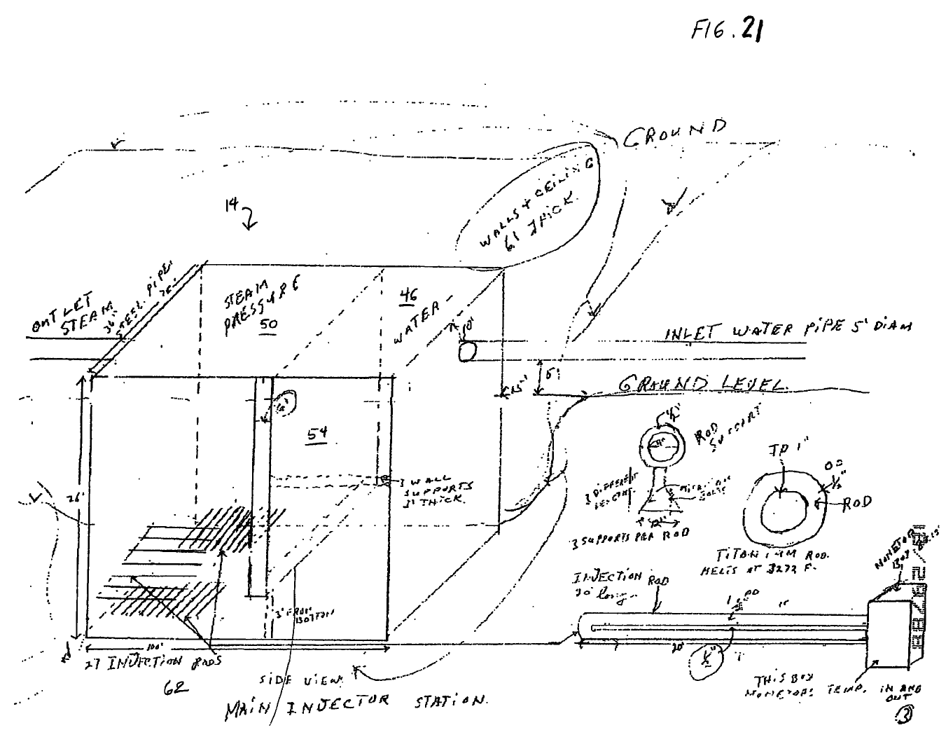

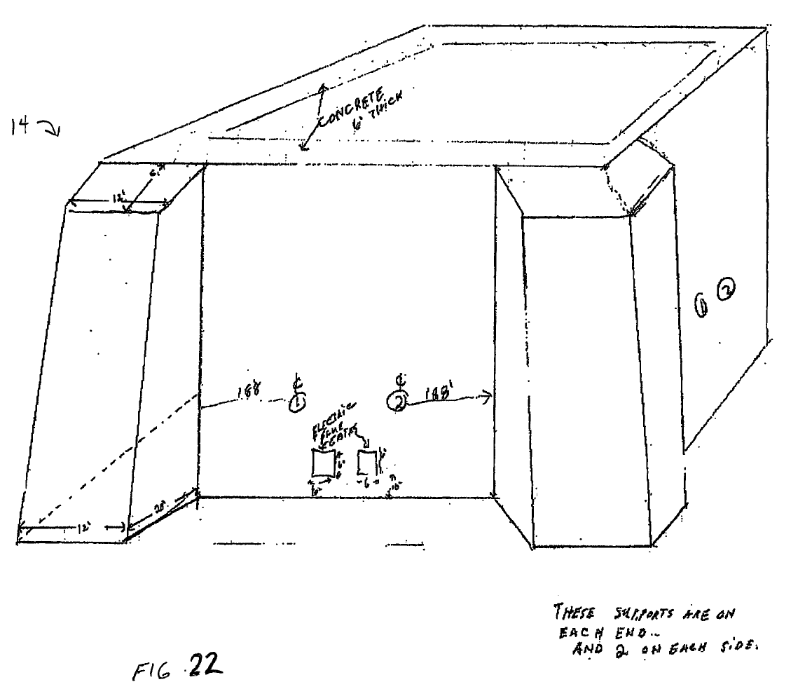

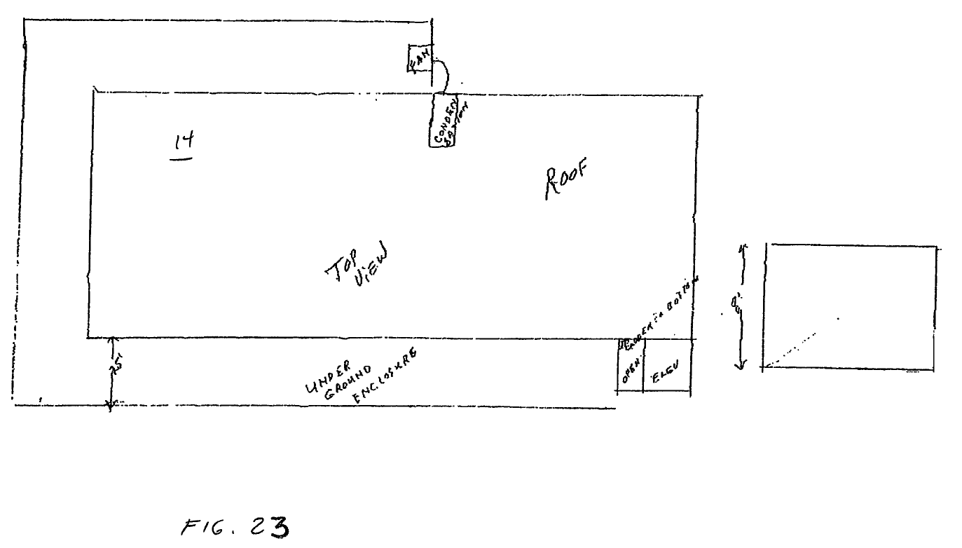

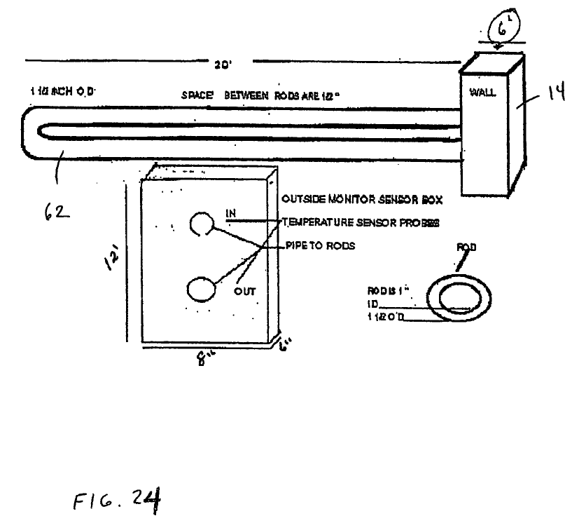

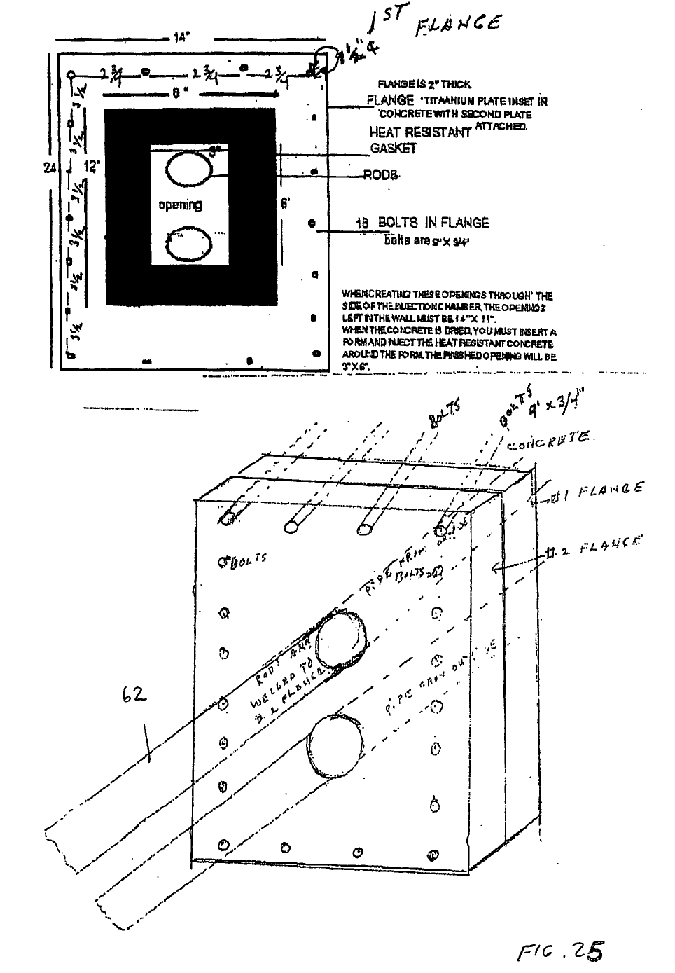

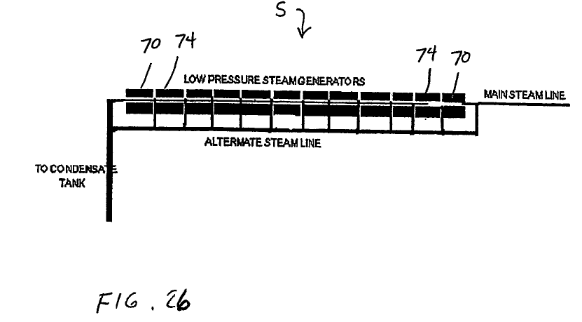

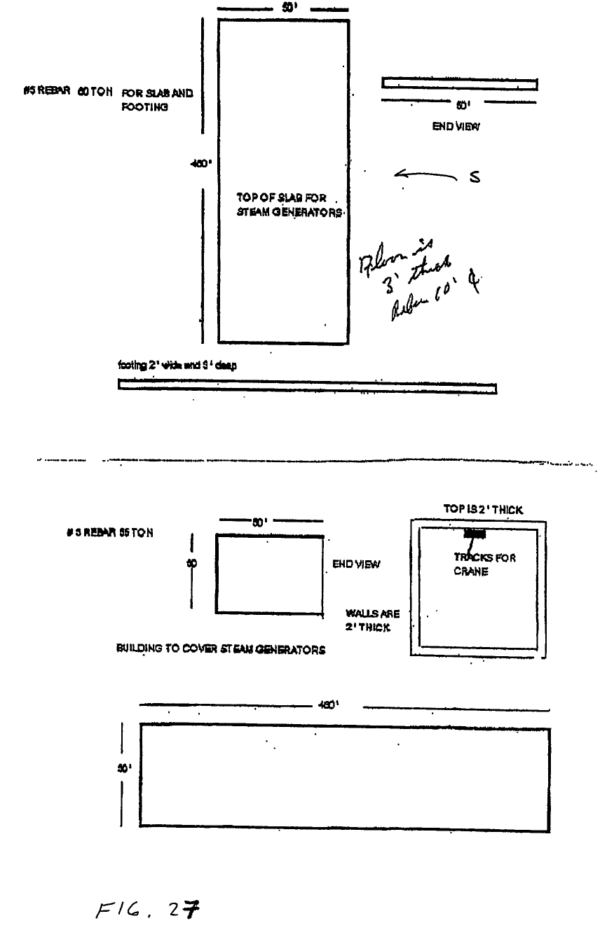

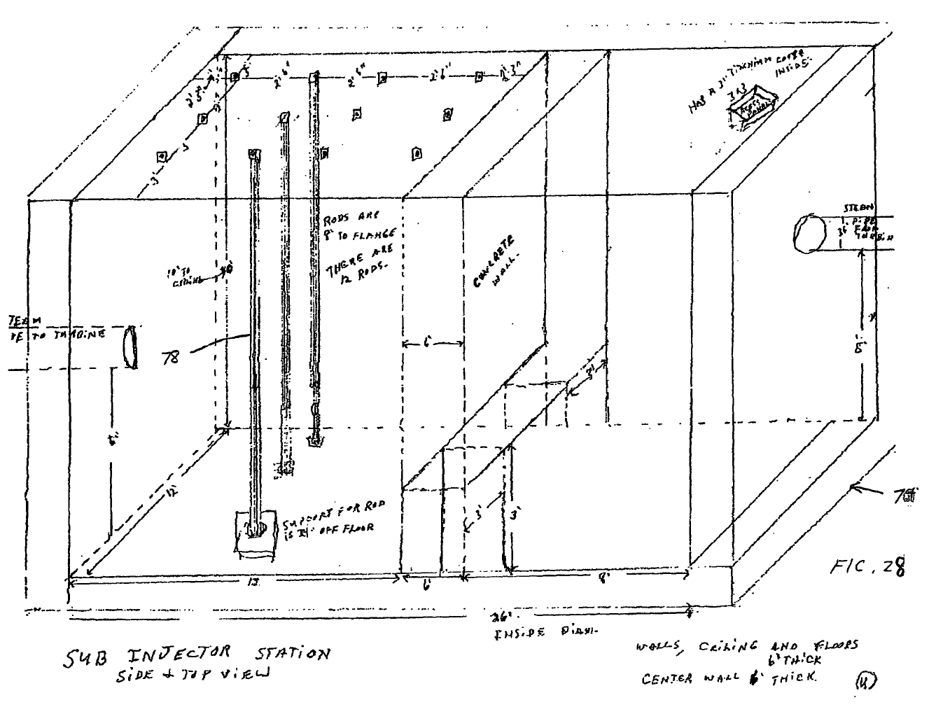

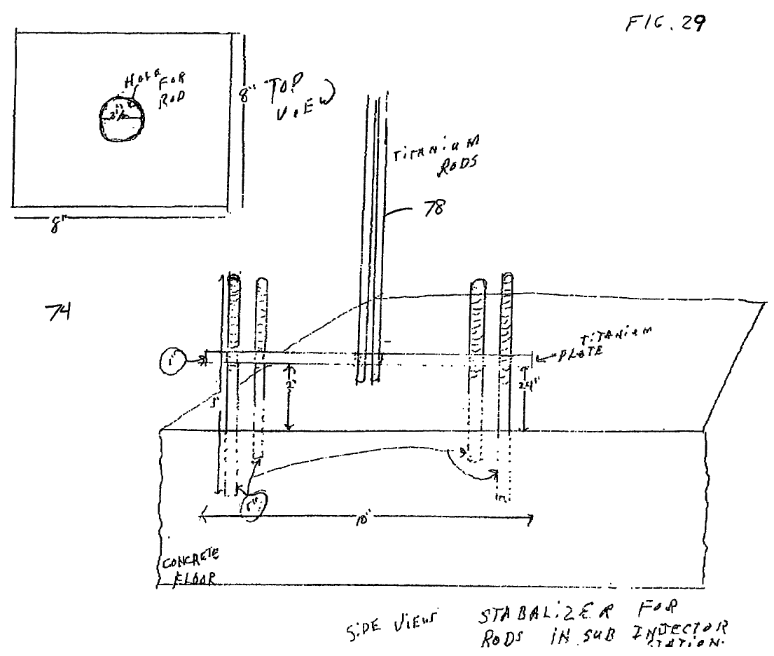

FIGS. 14-19 are views of the solar field shown in FIGS. 1-4 and of components of the solar field.

FIGS. 20-25 are views of the injection chamber shown in FIGS. 14 and of components of the injection chamber.

FIG. 26 is a diagram of a portion of the system shown in FIG. 14.

FIG. 27 are views of the series of steam generators.

FIGS. 28-29 are views of the steam booster substation shown in FIGS. 14 and of components of the substation.

Before one embodiment of the invention is explained in detail, it is to be understood that the invention is not limited in its application to the details of the construction and the arrangements of the components set forth in the following description or illustrated in the drawings. The invention is capable of other embodiments and of being practiced or carried out in various ways. Also, it is understood that the phraseology and terminology used herein is for the purpose of description and should not be regarded as limiting.

### DETAILED DESCRIPTION OF THE PREFERRED EMBODIMENT

Alternative constructions of an electricity-generating system 10 embodying the invention are illustrated in FIGS. 14. Generally, the system is a closed looped system using super-heated, high pressure steam to generate electricity. The system incorporates heat-resistant concrete, preferably in the form of panels P, to withstand the intense heat and pressure in portions of the system, such as in the injection chamber 14 and in the steam-booster substations 18. As explained below in more detail, this heat-resistant concrete is preferably formed of a pure mix of cement, silica sand, hardener, baking soda and liquid detergent, such as, Liquid ALL® manufactured by Lever Brothers company, headquartered in New York, N.Y.

The system includes (see FIGS. 1-11) a reservoir 22 in which water is stored under pressure (about 2,000 psi). The reservoir 22 includes a main reservoir tank 26 (and, in some constructions, may include a back-up reservoir tank 30). The main reservoir tank 26 includes a dry condensation unit 34 for condensing steam from the system and returning the condensed water to the water supply. In the illustrated construction, the main reservoir tank 26 is 400 feet wide by 400 feet long by 150 feet high. As shown in FIGS. 10-11, the main reservoir tank 26 includes internal beams and posts to provide structural support.

Water is supplied from the reservoir 22 through an approximately three foot opening (not shown) to provide sufficient pressure to power a hydroelectric generator 38. In the illustrated construction, the system includes two 50 MW hydroelectric generators 38 and 38′ which are operated to generate at least enough electricity to power the system 10. As shown in FIG. 12, the generators 38 and 38′ are enclosed within a building. The combination of the pressure in the main reservoir tank 26 (i.e., 2,000 psi) and the three foot opening provides enough pressure to turn the turbines in the hydroelectric generators 38 and/or 38′. In an alternative construction (not shown), the main reservoir tank 26 may not be pressurized, and a larger opening may be provided to supply water to the generators 38 and 38′.

The system also includes (see FIGS. 1-4 and 14-19) a solar field 42 for heating water from the reservoir 22. The solar field 42 is approximately five acres and, in the solar field 42, the water is pre-heated to between 150 degrees Fahrenheit (° F.) and 275° F. The pre-heated water is then fed to the injection chamber 14.

It should be understood that in other constructions (not shown), another source of water and/or of pre-heated water may be used. For example, a natural source of steam pressure may be provided to replace the reservoir 22 and/or the solar field 42.

As shown in more detail in FIGS. 20-25, the injection chamber 14 includes a water chamber 46, which receives the pre-heated water from the solar field 42, and a steam chamber 50, in which the pre-heated water is converted to steam. A wall 54 having lower openings 58 separates the chambers 46 and 50. A series of rods or pipes 62 (having an inner diameter of about 3 inches and an outer diameter of about 4 inches), preferably formed of titanium, are positioned adjacent the bottom wall of the steam chamber 50. Liquid metal, such as, for example, mercury, which is super-heated (between 1000° F. and 2500° F.), is supplied from a parabolic dish solar array 66 (including one or more parabolic dishes and, preferably, six parabolic dishes) through the pipes 62.

In operation of the injection chamber 14, pre-heated water is supplied through the openings 58 to the steam chamber 50 and is immediately converted to steam by the super-heated liquid metal flowing through the pipes 62. The super-heated steam is then fed from the injection chamber 14 through the electricity-generating portion of the system 10.

As the super-heated liquid metal in the pipes 62 converts the water to steam in the steam chamber 50, the liquid metal is cooled from about 2500° F. (as it enters the steam chamber 50) down to about 500° F. (as the liquid metal exits the sections of pipe 62 in the steam chamber 50 to return to the solar array 66). To re-heat the returning liquid metal and to increase the pressure in the return line, induction coils (not shown) are provided on sections of the return line to heat these sections of the return line. As the cooler liquid metal flows through the heated sections of the return line, the liquid metal is re-heated up to about 2000° F., and the pressure in the return line increases up to about 1100 psi. The spaced-apart induction coil sections continue to boost the temperature of the liquid metal and the pressure in the return line until the re-heated liquid metal re-enters the solar array 66 to be re-heated up to the operating temperature of about 2500° F.

In the steam chamber 50, the operating temperature is between 1000° F. and 2500° F., and the operating pressure is about 2,000 psi. To withstand the intense heat and pressure in the injection chamber 14, heat-resistant concrete panels P are fixed to the interior walls of the injection chamber 14 (in at least the steam chamber 50).

In the illustrated construction, the inner dimensions of the injection chamber 14 are 76 feet wide by 100 feet long by 76 feet high To withstand the intense pressure, the walls of the injection chamber are 68 feet thick and have kickers to provide additional support. Also, the roof of the injection chamber 14 has concrete beams extending across, which are post-tensioned, and is at least 6 feet thick.

As mentioned above, to withstand the intense heat, the interior walls of the injection chamber 14 are provided with heat-resistant concrete panels P which, in the preferred embodiment, are 7 feet by 7 feet by 6 inches. The heat-resistant concrete panels P may be provided in both the water chamber 46 and the steam chamber 50 but are only required in the steam chamber 50.

The super-heated, high pressure steam is supplied from the injection chamber 14 to a series S of steam generators 70. In the illustrated construction, each steam generator 70 is a 1300 MW low-pressure steam generator. A steam-booster substation 74 is provided between each steam generator 70. As shown in FIG. 27, a building covers the series S of generators 70 and substations 74.

It should be understood that, in other constructions (not shown) the generator series S may include additional generators 70 and substations 74 and may include another parabolic dish solar array (not shown) to supply the additional substations.

As shown in more detail in FIGS. 28-29, the booster substations 74 include pipes 78, preferably formed of titanium, which carry super-heated liquid metal through each booster substation 74 to maintain the temperature and pressure of the steam as it flows through the generator series S. A parabolic dish solar array 82 (including one or more parabolic dishes and, preferably, four parabolic dishes) feeds super-heated liquid metal (between 1000° F. and 2500° F.) to each booster substation 74, and a separate solar array 82 is preferably provided for each booster substation 74. However, in some constructions, a manifold 86 may supply super-heated metal liquid from a single parabolic dish solar array 82 through more than one booster substation 74. To withstand the intense heat and pressure in the booster substation 74, heat-resistant concrete panels P are also fixed to the interior walls of the substations 74.

Once the steam exits the generator series S, the steam flows, under it's own pressure, back to the reservoir 22. Along the way, condensing hot water is fed to the solar field 42, reducing the pre-heating requirements of the solar field 42. The steam enters the condensing unit 34 on the top of the main reservoir tank 26, and the condensed water re-enters the water supply in the reservoir 22.

Preferably, in the high-temperature portions of the system 10, such as the injection chamber 14 and the series S of generators 70 and substations 74, all pipes are formed of or have the high-temperature surfaces lined with titanium, which has a very high melting point Also, in these high temperature areas, all exposed metal in the high-temperature areas are formed of or the high temperature surfaces are coated with titanium. Such exposed metal may include, for example, the heads of bolts used to fix the heat-resistant concrete panels P to the interior walls of the injection chamber 14 and the interior walls of the booster substations 74 and the flanges supporting the pipes 62 and 78.

In the illustrated construction, the structures (the reservoir tanks 26 and 30, injection chamber 14, booster substations 74 and the buildings covering the separate structures (such as the generators 38 and 38′ and the series S of generators 70 and substations 74)) are formed of monolithically poured concrete. Cooling pipes (not shown) are formed in the concrete of the structures, and, during curing of the concrete, cooling liquid, such as, for example, nitrogen, is supplied through the cooling pipes to cure the concrete. In addition, all metal used in the construction of these high temperature portions of the system 10, such as, for example, the cooling pipes and the rebar used in the structures of the injection chamber 14 and the series S of generators 70 and substations, are formed of or have the outer surfaces coated with titanium. This prevents the structural metal from melting if it comes into contact with steam or other high temperature material.

The system 10 also includes a control system (not shown) for monitoring and controlling the construction and operation of the components of the system 10. These conditions are monitored and controlled to ensure the quality of the construction, to optimize the performance and electricity-generation of the system 10 and to avoid any problems with operation of the system 10.

The control system includes sensors (not shown) supported throughout the system and connected to one or more control computers. The sensors monitor the conditions (such as, for example, the temperature, pressure, humidity, etc.) in the components of the system during construction and operation and send signals to the control computer(s) representing these conditions.

The control computer(s) evaluate the signals and control the components in accordance with the conditions in the system 10. For example, the control computer(s) control the pouring of concrete during construction of the structures. During operation of the system 10, the control computer(s) -control the flow of water from the reservoir 22, through the solar field 42 and to the injection chamber 14. Also, the control computer(s) control the flow of super-heated liquid metal through the pipes 62 in the steam chamber 50 and through the pipes 78 in the booster substations 74. In addition, the control computer(s) control the flow of steam through the series S of steam generator 70.

Heat-Resistant Concrete

Again, the heat-resistant concrete and heat-resistant panels are able to withstand intense heat and pressure in portions of the system, such as in the injection chamber 14 and in the steam-booster substations 18. The heat-resistant concrete composition generally comprises:
about one-half part to about one and one-half parts cement;
about one-half part to about one and one-half parts silica sand;
about one-eighth part to about three-eighth part fine silica sand;
about one-eighth to about three-eighth part hardener;
about one-quarter to about three-quarter part baking-soda; and
greater than zero and less than about one part detergent.

In one embodiment of the invention, the heat-resistant concrete composition comprises about one-half part cement, one-half part silica sand, one-eighth part fine silica sand, one-eighth part hardener, one-half part baking soda and about one-third part liquid detergent. Most preferably, the composition comprises about one part cement, about one part silica sand, about one-quarter part fine silica sand, about one-quarter part hardener, about one-half part baking soda and greater than zero and less than about one part detergent.

Cements

Suitable cements for use with the invention include Quikcrete® manufactured by Quikcrete Companies, headquartered at 2987 Clairmont Road, Suite 500, Atlanta, Ga. 30329. Other cements which can be used to produce the heat-resistant concrete include cement nos. 1-3 manufactured by Portland Cement, headquartered in Chicago, Ill. In general, most types of cement are suitable for use in the composition. The type of cement selected will depend on regional availability and other aesthetic concerns.

Silica Sands

Typically, two types of silica sand having different particulate sizes are employed in the composition: a silica sand and a more fine silica sand. It is preferred that these two sands exhibit high uniformity. It is also important that the silica sands be free of contaminants and dirt. Contaminants and dirt tend to inhibit the formation of a uniform concrete and may also make the heat-resistant properties of the concrete less predictable. The fine silica sand allows for the formation of a concrete substantially devoid of gaps and pockets in the concrete. Silica sand having very coarse particles is more likely to yield gaps and pockets in the resulting concrete.

Concrete Hardeners

Concrete hardeners facilitate the curing of the cement and include those manufactured by Increte Systems. Hardeners are used in many concrete applications in which durable hard surface is desired such as flat work, stamped concrete and as a chemical staining base. Concrete hardeners provide several advantages when used in the compositions described herein. For example, hardeners allow the concrete to resist fading and discoloration, while also reducing porosity and increasing surface density. In addition, hardeners considerably strengthen and harden the surface of the resulting concrete, while also adding workability to the resulting surface to aid in stamping. The hardeners allow the concrete to withstand more pressure and to cure faster, and also provide excellent abrasion and wear resistance.

Baking Soda

Any sodium bicarbonate or baling soda can be used in the concrete composition, however, Arm & Hammer® baking soda, manufactured by Church & Dwight Company, headquartered at Alchern Road, Green River Wyo. 82935, is preferred.

Detergents

The detergent in the composition provides the necessary heat-resistant properties to the concrete. The detergents used in conjunction with the invention comprise at least one detergent surfactant. The detergent surfactant can be selected from nonionic, anionic, cationic, zwitterionic, amphoteric and semi-polar nonionic surfactants and mixtures thereof. The surfactant may comprise a substantial portion of nonionic surfactant together with either an anionic surfactant, a semi-polar nonionic surfactant, or cationic surfactant or mixtures thereof. The detergent may optionally include buffering agents, stabilizers, brighteners, colorants, and perfumes.

Nonionic Surfactants

The nonionic surfactants are conventionally produced by condensing ethylene oxide with a hydrocarbon having a reactive hydrogen atom, e.g., a hydroxyl, carboxyl, amino, or amido group, in the presence of an acidic or basic catalyst. Nonionic surfactants have the general formula RA(CH₂CH₂O)ₙH wherein R represents the hydrophobic moiety, A represents the group carrying the reactive hydrogen atom and n represents the average number of ethylene oxide moieties. R typically contains from about 8 to about 22 carbon atoms, but can also be formed by the condensation of propylene oxide with molecular weight compound and usually varies from about 2 to about 24.

The hydrophobic moiety of the nonionic compound may be a primary or secondary, straight or slightly branched, aliphatic alcohol having from about 8 to about 24, and from about 12 to about 20 carbon atoms. A more complete disclosure of suitable nonionic surfactants can be found in U.S. Pat. No. 4,111,855 issued to Barrat, et al., which is hereby incorporated herein by reference.

Other nonionic surfactants useful in the composition include ethoxylated alcohols or ethoxylated alkyl phenols of the formula R(OC₂H₄)ₙOH, wherein R is an aliphatic hydrocarbon radical containing from about 10 to about 18 carbon atoms or an alkyl phenyl radical in which the alkyl group contains from about 8 to about 15 carbon atoms, n is from about 2 to about 9 and the nonionic surfactant has an HLB (hydrophilic-lipophilic balance, as defined in Nonionic Surfactants by M. J. Schick, Marcel Dekker, Inc., 1966, pages 607-613, incorporated herein by reference) of from about 5 to about 14, or from about 6 to about 13. Examples of such surfactants are listed in U.S. Pat. No. 3,717,630, Booth, issued Feb. 20, 1973, and U.S. Pat. No. 3,332,880, Kessler et al, issued Jul. 25, 1967, both incorporated herein by reference.

Moreover, other nonionic surfactants include the condensation products of alkyl phenols having an alkyl group containing from about 8 to 15 carbon atoms in either a straight chain or branched chain configuration with ethylene oxide, said ethylene oxide being present in an amount equal to 2 to 9 moles of ethylene oxide per mole of alkyl phenol. The alkyl substituent in such compounds can be derived, for example, from polymerized propylene, diisobutylene, and the like. Examples of compounds of this type include nonyl phenol condensed with about 9 moles of ethylene oxide per mole of nonyl phenol; and dodecyl phenol condensed with about 8 moles of ethylene oxide per mole of phenol.

Other useful nonionic surfactants are the condensation products of aliphatic alcohols with from about 2 to about 9 moles of ethylene oxide. The alkyl chain of the aliphatic alcohol can either be straight or branched, primary or secondary, and should contain from about 10 to about 18 carbon atoms. Examples of such ethoxylated alcohols include the condensation product of myristyl alcohol condensed with about 9 moles of ethylene oxide per mole of alcohol; and the condensation product of about 7 moles of ethylene oxide with coconut alcohol (a mixture of fatty alcohols with alkyl chains varying in length from 10 to 14 carbon atoms). Examples of commercially available nonionic surfactants in this type Tergitol 15-S-9, marketed by Union Carbide Corporation, Neodol 45-9, Neodol 23-6.5, Neodol 45-7, and Neodol 45-4, marketed by Shell Chemical Company, and Kyro EOB, marketed by The Procter & Gamble Company.

Furthermore, other nonionic surfactants include those having the formula R(OC₂H₄)ₙOH, wherein R is a primary alkyl chain containing an average of from about 10 to about 18 carbon atoms, and n is an average of from about 2 to about 9. These nonionic surfactants have an HLB (hydrophilic-lipophilic balance) of from about 5 to about 14.

Other examples of nonionic surfactants include the condensation product of coconut alcohol with 5 moles of ethylene oxide; the condensation product of coconut alcohol with 6 moles of ethylene oxide; the condensation product of C₁₂₋₁₅ alcohol with 7 moles of ethylene oxide; the condensation product of C₁₂₋₁₅ alcohol with 9 moles of ethylene oxide; the condensation product of C₁₄₋₁₅ alcohol with 2.25 moles of ethylene oxide; the condensation product of C₁₄₋₁₅ alcohol with 7 moles of ethylene oxide; the condensation product of C₉₋₁₁ alcohol with 8 moles of ethylene oxide, which is stripped so as to remove unethoxylated and lower ethoxylate fractions; the condensation product of C₁₂₋₁₃ alcohol with 6.5 moles of ethylene oxide, and this same alcohol ethoxylate which is stripped so as to remove unethoxylated and lower ethoxylate fractions. One class of such surfactants utilizes alcohols which contain about 20% 2-methyl branched isomers, and are commercially available, under the tradename Neodol, from Shell Chemical Company. The condensation product of tallow alcohol with 9 moles of ethylene oxide is also a nonionic surfactant for use herein. Other nonionic surfactants for use in the compositions of the present invention include the condensation product of coconut alcohol with 5 moles of ethylene oxide, the condensation product of C₁₂₋₁₃ alcohol with 6.5 moles of ethylene oxide, the condensation product of C₁₂₋₁₅ alcohol with 7 moles of ethylene oxide, the condensation product of C₁₄₋₁₅ alcohol with 7 moles of ethylene oxide, and the same material stripped of unethoxylated alcohol and lower ethoxylated fractions, and mixtures thereof.

Anionic Surfactants

Synthetic anionic surfactants can be represented by the general formula R₁SO₃ M wherein R₁ represents a hydrocarbon group selected from the group consisting of straight or branched alkyl radicals containing from about 8 to about 24 carbon atoms and alkyl phenyl radicals containing from about 9 to about 15 carbon atoms in the alkyl group. M is a salt forming cation which typically is selected from the group consisting of sodium, potassium, ammonium, monoalkanolammonium, dialkanolammonium, trialkanolammonium, and magnesium cations and mixtures thereof.

An example of an anionic surfactant is a water-soluble salt of an alkylbenzene sulfonic acid containing from about 9 to about 15 carbon atoms in the alkyl group. Another synthetic anionic surfactant is a water-soluble salt of an alkyl polyethoxylate ether sulfate wherein the alkyl group contains from about 8 to about 24. Other suitable anionic surfactants are disclosed in U.S. Pat. No. 4,170,565, Flesher et al, issued Oct. 9, 1979, incorporated herein by reference.

Other suitable anionic surfactants can include soaps and fatty acids containing from about 8 to about 24 carbon atoms.

Other useful anionic surfactants include the water-soluble salts, particularly the alkali metal, ammonium and alkylolammonium (e.g., monoethanolammonium or triethanolammonium) salts, of organic sulfuric reaction products having in their molecular structure an alkyl group containing from about 10 to about 20 carbon atoms and a sulfonic acid or sulfuric acid ester group. (Included in the term “alkyl” is the alkyl portion of aryl groups.) Examples of this group of synthetic surfactants are the alkyl sulfates, especially those obtained by sulfating the higher alcohols (C₈-C₁₈ carbon atoms) such as those produced by reducing the glycerides of tallow or coconut oil; and the alkylbenzene sulfonates in which the alkyl group contains from about 9 to about 15 carbon atoms, in straight chain or branched chain configuration, e.g., those of the type described in U.S. Pat. Nos. 2,220,099 and 2,477,383 both of which are hereby incorporated by reference. Especially valuable are linear straight chain alkylbenzene sulfonates in which the average number of carbon atoms in the alkyl group is from about 11 to 14.

Other anionic surfactants include the water-soluble salts of paraffin sulfonates containing from about 8 to about 24 carbon atoms; alkyl glyceryl ether sulfonates, especially those ethers of C₈₋₁₈ alcohols (e.g., those derived from tallow and coconut oil); alkyl phenol ethylene oxide ether sulfates containing from about 1 to about 4 units of ethylene oxide per molecule and from about 8 to about 12 carbon atoms in the alkyl group; and alkyl ethylene oxide ether sulfates containing about 1 to about 4 units of ethylene oxide per molecule and from about 10 to about 20 carbon atoms in the alkyl group.

Other useful anionic surfactants include the water-soluble salts of esters of alpha-sulfonated fatty acids containing from about 6 to 20 carbon atoms in the fatty acid group and from about 1 to 10 carbon atoms in the ester group; water-soluble salts of 2-acyloxy-alkane-1-sulfonic acids containing from about 2 to 9 carbon atoms in the acyl group and from about 9 to about 23 carbon atoms in the alkane moiety; water-soluble salts of olefin sulfonates containing from about 12 to 24 carbon atoms; and beta-alkyloxy alkane sulfonates containing from about 1 to 3 carbon atoms in the alkyl group and from about 8 to 20 carbon atoms in the alkane moiety.

Furthermore, other anionic surfactants include C₁₀-C₁₈ alkyl sulfates and alkyl ethoxy sulfates containing an average of up to about 4 ethylene oxide units per mole of alkyl sulfate, C₁₀-C₁₃ linear alkylbenzene sulfonates, and mixtures thereof Unethoxylated alkyl sulfates may also be used.

Cationic Surfactants

Suitable cationic surfactants have the general formula (R²)ₘ(R³)ₓY_{L}Z wherein each R² is an organic group containing a straight or branched alkyl or alkenyl group optionally substituted with up to three phenyl or hydroxy groups and optionally interrupted by up to four structures selected from the group consisting of 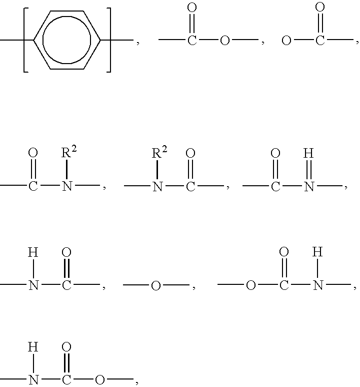
and mixtures thereof each R² containing from about 8 to 22 carbon atoms, and which may additionally contain up to about 12 ethylene oxide groups, m is a number from 1 to 3, each R³ is an alkyl or hydroxyalkyl group containing from 1 to 4 carbon atoms or a benzyl group with no more than one R³ in a molecule being benzyl, x is a number from 0 to 11, the remainder of any carbon atom positions being filled by hydrogens, Y is selected from the group consisting of:

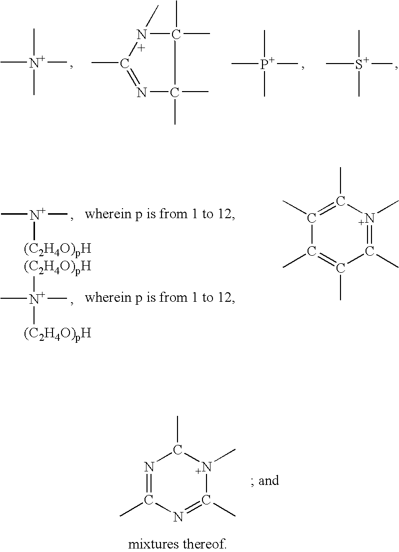

A more complete disclosure can be found in U.S. Pat. No. 4,228,044 by Cushman M. Cambre for Laundry Detergent Composition Having Enhanced Particulate Soil Removal and Antiredeposition Performance, issued Oct. 14, 1980, said patent being incorporated herein by reference. Care should be taken in including cationic materials, including surfactants since some cationic materials have been found to decrease enzyme effectiveness.

The cationic surfactants used in the compositions of the present invention may also be of the di-long chain quaternary ammonium type, having two chains which contain an average of from about 12 to about 22 carbon atoms. The remaining groups, if any, attached to the quaternary nitrogen atom are C₁ to C₄ alkyl or hydroxyalkyl groups. Although it is preferred that the long chains be alkyl groups, these chains can contain hydroxy groups or can contain heteroatoms or other linkages, such as double or triple carbon-carbon bonds, and ester, amide, or ether linkages, as long as each chain falls within the above carbon atom ranges.

Mixtures of the above surfactants are also useful in the present invention. These cationic surfactants can also be mixed with other types of cationic surfactants, such as sulfonium, phosphonium, and mono- or tri-long chain quaternary ammonium materials, as long as the amount of required cationic surfactant falls within the nonionic: cationic ratios herein. Examples of cationic surfactants which can be used in combination with those required herein are described in U.S. Pat. No. 4,259,217, Murphy, U.S. Pat. No. 4,222,905, Cockrell, U.S. Pat. No. 4,260,529, Letton, and U.S. Pat. No. 4,228,042, Letton, all incorporated herein by reference.

Other cationic surfactants include ditallowalkyldimethyl (or diethyl or dihydroxyethyl) ammonium chloride, ditallowalkyldimethylammonium methyl sulfate, dihexadecylalkyl (C₁₆) dimethyl (or diethyl, or dihydroxyethyl) ammonium chloride, dioctodecylalkyl (C₁₈)dimethylammonium chloride, dieicosylalkyl(C₂₀) dimethylammonium chloride, methyl (1) tallowalkyl amido ethyl (2) tallowalkyl imidazolinium methyl sulfate (commercially available as Varisoft 475 from Ashland Chemical Company), or mixtures of those surfactants. Typical cationic surfactants are ditallowalkyldimethylammonium methyl sulfate, methyl (1) tallowalkyl amido ethyl (2) tallowalkyl imidazolinium methyl sulfate, and mixtures of those surfactants, with ditallowalkyldimethylammonium chloride being typical.

Zwitterionic Surfactants

Zwitterionic surfactants include derivatives of aliphatic quaternary ammonium, phosphonium, and sulphonium compounds in which the aliphatic moiety can be straight or branched chain and wherein one of the aliphatic substituents contains from about 8 to 24 carbon atoms and one contains an anionic water-solubilizing group. Typical zwitterionic materials are the ethoxylated ammonium sulfonates and sulfates disclosed in U.S. Pat. Nos. 3,925,262, Laughlin et al, issued Dec. 9, 1975 and 3,929,678, Laughlin et al, issued Dec. 30, 1975, said patents being incorporated herein by reference.

Ampholytic Surfactants

Ampholytic surfactants include derivatives of aliphatic heterocyclic secondary and ternary amines in which the aliphatic moiety can be straight chain or branched and wherein one of the aliphatic substituents contains from about 8 to about 24 carbon atoms and at least one aliphatic substituent contains an anionic water-solubilizing group.

Semi-Polar Nonionic Surfactants

Semi-polar nonionic surfactants include water-soluble amine oxides containing 1 alkyl or hydroxy alkyl moiety of from about 8 to about 28 carbon atoms and 2 moieties selected from the group consisting of alkyl groups and hydroxy alkyl groups, containing from 1 to about 3 carbon atoms which can optionally be joined into ring structures; water-soluble phosphine oxides containing 1 alkyl or hydroxy alkyl moiety of from about 8 to about 28 and 2 moieties selected from the group consisting of alkyl groups and hydroxy alkyl groups, containing from about 1 to about 3 carbon atoms; and water-soluble sulfoxides containing 1 alkyl or hydroxy alkyl moiety of from about 8 to about 28 carbon atoms and a moiety selected from the group consisting of alkyl and hydroxy alkyl moieties of from 1 to 3 carbon atoms.

Buffering Agents

Buffering agents include monoethanolamine, diethanolamine or triethanolamine, although monoethanolamine is preferred.

Stabilizers

The stabilization of enzymes in the detergents is desired, however, this may be particularly difficult in built, heavy-duty liquid detergents containing high levels of anionic surfactants and water. Anionic surfactants, especially alkyl sulfates, tend to denature enzymes and render them inactive. Detergent builders can sequester the calcium ion needed for enzyme activity and/or stability.

While many different enzyme stabilizers can be used in the compositions, the combination of boric acid and calcium ion, alternatively with a polyol, provides good stability in the present compositions.

The compositions herein may contain from about 0.25% to about 10% by weight of boric acid or a compound capable of forming boric acid in the composition (calculated on the basis of the boric acid). Boric acid may be used, although other compounds such as boric oxide, borax and other alkali metal borates (e.g., sodium ortho-, meta- and pyroborate, and sodium pentaborate) are suitable. Substituted boric acids (e.g., phenylboronic acid, butane boronic acid, and p-bromo phenylboronic acid) can also be used in place of boric acid.

The composition also contains from about 1 to about 30 millimoles of calcium ion per liter. The level of calcium ion should be selected so that there is always some minimum level available for the enzyme, after allowing for complexation with builders, fatty acid, etc., in the composition. Any water-soluble calcium salt can be used as the source of calcium ion, including calcium chloride, calcium formate, and calcium acetate. A small amount of calcium ion, generally from about 0.05 to about 0.4 millimoles per liter, is often also present in the composition due to calcium in the enzyme slurry and formula water.

The compositions may also contain any of the water-soluble formates described in U.S. Pat. No. 4,318,818, Letton et al, issued Mar. 9, 1982, incorporated herein by reference. Formate may be present at a level of from about 0.05% to about 5%, by weight of the composition.

Brighteners

Brighteners are an optional component in the detergent. Brighteners such as anionic brighteners of the formula may be used:

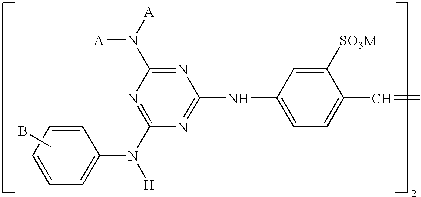

Wherein each A is hydrogen, methyl, ethyl, isopropyl, 2-hydroxyethyl, 2-hydroxypropyl, or propanamido, or taken together are morpholino or anilino; and each B is hydrogen or —SO₃M, wherein M is a compatible cation and the total number of —SO₃M groups in the molecule is from 3 to 6 with no more than 2 —SO₃M groups per anilino group.

Typical brighteners may contain from 3 to 5, and especially 4, —SO₃M groups. While M can be any suitable cation, such as potassium, ammonium, or substituted ammonium (e.g., mono-, di-, or triethanolammonium).

Typical brighteners are those in which A in the above formula is 2-hydroxyethyl or 2-hydroxypropyl, or taken together form a morpholino group with the nitrogen atom.

Examples of brighteners of the above class are tetrasodium 4,4′-bis{{4-[bis(2-hydroxyethyl)amino]-6-(p-sulfoanilino)-1,3,5-triazin-2-yl}amino}-2,2′-stilbene disulfonate, commercially available as Tinopal DCS (powder) from Ciba-Geigy, and as Phorwhite BBU, (powder and liquid) from Mobay; and the corresponding material in which the 2-hydroxyethyl groups are replaced with 2-hydroxypropyl groups, commercially available as Phorwhite BRU from Mobay.

Heat-Resistant Aggregates

The concrete compositions may also comprise heat-resistant aggregates which include, but are not limited to, limestone, shale and man-made products.

### EXAMPLE

In one embodiment of the heat-resistant concrete, the detergent in the concrete comprises a non-ionic surfactant The detergent, however, can also comprise other ingredients which may also improve the heat resistance of the concrete. These other ingredients in this embodiment include an anionic surfactant and monoethanolamine. The detergent also comprises water. These ingredients are added to the concrete composition as desired in order to produce concrete having a desired consistency and desired heat-resistance. One composition particularly suitable for use in the invention comprises, by volume:

| | |
|---|---|
| Water | 65-75%; |
| Anionic surfactant | 15-25%; |
| Non-ionic surfactant | 5-10%; and |
| Monoethanolamine | 1-5%. |

In another embodiment, the detergent is a non-phosphorus liquid detergent such as Liquid ALL®, although other liquid non-ionic detergents are suitable for use with the invention. The chemical composition of Liquid ALL® manufactured by Lever Brothers Company, headquartered at 390 Park Avenue, New York, N.Y. 10022, by volume comprises anionic surfactants, nonionic surfactants, a buffering agent, stabilizer, brightening agent, colorant and perfume. Other liquid laundry detergents that are commercially available may also work in conjunction with the invention. In addition, the detergents, compositions and components recited in the following patents (all of which are hereby incorporated by reference) may also be used in conjunction with the invention: U.S. Pat. No. 4,318,818 issued to Letton et al., U.S. Pat. No. 4,446,042 issued to Leslie, U.S. Pat. No. issued to 4,537,706 Severson, Jr., U.S. Pat. No. 4,537,707 issued to Herman, U.S. Pat. No. 4,561,998 issued to Wertz, et al., Moeddel, U.S. Pat. No. 4,597,898 issued to Ghosh, U.S. Pat. No. 4,968,451 issued to Scheibel et al., U.S. Pat. No. 5,194,639 issued to Connor et al., U.S. Pat. No. 5,288,431 issued to Huber et al., U.S. Pat. No. 5,458,809 issued to Fredj, et al., U.S. Pat. No. 5,458,810 issued to Riddell, et al., U.S. Pat. No. 5,460,752 issued to Fredj, et al., U.S. Pat. No. 5,466,802 issued to Pananodiker, et al., U.S. Pat. No. 5,470,507 issued to Fredj, et al., U.S. Pat. No. 5,565,145 issued to Watson, et al., U.S. Pat. No. 5,916,862 issued to Morelli, et al.

The process for preparing the heat-resistant concrete comprises mixing the fine silica sand with the hardener to form a mixture. Subsequently, while keeping the mixture dry, regular sand and cement are added and mixed therein. Baking soda is also slowly added and carefully mixed so as not to introduce unnecessary air into the mixture. Too much air tends to create voids and pockets in the resulting concrete. Finally, sufficient detergent is added to bind the components without making the mixture too wet or soapy. The resulting heat-resistant cement ideally exhibits a two-inch slump, and can withstand temperatures up to 2000° F. Generally, no additional water is added to the mixture.

1. An electricity-generating system comprising:
a reservoir storing water under pressure;
a generator in fluid communication with the reservoir, the generator receiving pressurized water and being operable to generate electricity to power the system;
a solar field in fluid communication with the generator, the solar field receiving water from the generator and being operable to pre-heat the water;
an injection chamber in fluid communication with the solar field, the injection chamber receiving pre-heated water and being operable to convert the pre-heated water to super-heated steam;
a parabolic dish solar array providing super-heated steam through pipes in the injection chamber to convert the pre-heated water to super-heated steam in the injection chamber;
a series of steam generators communicating with the injection chamber and with the reservoir, the steam generators receiving steam from the injection chamber and being operable to generate electricity;
steam-booster substations in fluid communication with the series of steam generators, the substations being operable to maintain temperature and pressure of the steam as the steam flows through the series of steam generators, the steam being fed from the series of steam generators to the reservoir and condensed to re-enter the water supply; and
a parabolic dish solar array feeding super-heated water through a manifold and through pipes in each booster substation;
wherein heat-resistant concrete panels are provided on an interior surface of the injection chamber and on an interior surface of the substations.

2. An electricity-generating system comprising:
an injection chamber receiving pre-heated water and being operable to convert the pre-heated water to super-heated steam;
a series of steam generators communicating with the injection chamber, the steam generators receiving steam from the injection chamber and being operable to generate electricity; and
a steam-booster substation in fluid communication with the series of steam generators, the substation being operable to maintain temperature and pressure of the steam as the steam flows through the series of steam generators;
wherein heat-resistant concrete is provided on an interior surface of at least one of the injection chamber and the substation.

3. The system as set forth in claim 2 wherein the heat-resistant concrete comprises cement and a detergent comprising at least one of a nonionic surfactant, an anionic surfactant, a cationic surfactant, a zwitterionic surfactant, an amphoteric surfactant, a semi-polar surfactant and a mixture thereof.

4. The system as set forth in claim 2 wherein heat-resistant concrete is provided on an interior surface of the injection chamber and on an interior surface of the substation.

5. The system as set forth in claim 2 wherein the interior surface of the at least one of the injection chamber and the substation include heat-resistant concrete panels.

6. The system as set forth in claim 5 wherein the interior surface of the injection chamber and the interior surface of the substation include heat-resistant concrete panels.

7. The system as set forth in claim 2 and further comprising:
a reservoir storing water under pressure; and
a generator in fluid communication with the reservoir, the generator receiving pressurized water and being operable to generate electricity to power the system.

8. The system as set forth in claim 7 wherein the steam is fed from the series of steam generators to the reservoir and condensed to re-enter the water supply.

9. The system as set forth in claim 2 and further comprising a solar field operable to pre-heat the water, the solar field being in fluid communication with the injection chamber and being operable to feed pre-heated water to the injection chamber.

10. The system as set forth in claim 2 and further comprising a parabolic dish solar array providing super-heated steam to the injection chamber to convert the pre-heated water to super-heated steam in the injection chamber.

11. The system as set forth in claim 10 wherein the injection chamber includes pipes, and wherein the super-heated steam is provided to the injection chamber through the pipes.

12. The system as set forth in claim 11 wherein the pipes have an inner surface, the inner surface being formed of titanium.

13. The system as set forth in claim 12 wherein the pipes are formed of titanium.

14. The system as set forth in claim 2 and further comprising a parabolic dish solar array feeding super-heated water to the substation.

15. The system as set forth in claim 14 wherein the substation includes pipes, and wherein the super-heated steam is provided to the substation through the pipes.

16. The system as set forth in claim 15 wherein the pipes have an inner surface, the inner surface being formed of titanium.

17. The system as set forth in claim 16 wherein the pipes are formed of titanium.

18. The system as set forth in claim 14 and further comprising:
a second steam booster substation in fluid communication with the series of steam generators, the second substation being operable to maintain temperature and pressure of the steam as the steam flows through the series of steam generators; and
a manifold in fluid communication between the array and the first-mentioned substation and the second substation, super-heated steam being provided from the array through the manifold to the first-mentioned substation and to the second substation.

19. An injection chamber for use in an electricity-generating system, the system including a supply of water, a supply of super-heated water, and a steam generator using super-heated steam to generate electricity, the injection chamber comprises:
a water chamber receiving water from the water supply; and
a steam chamber communicating with the water chamber and with the generator, the steam chamber including interior walls, heat-resistant concrete being provided on the interior walls, the steam chamber including pipes carrying -super-heated water from the super-heated water supply, water being supplied from the water chamber to the steam chamber and being converted to super-heated steam by the super-heated water flowing through the pipes, the super-heated steam being supplied to the generator to generate electricity.

20. The injection chamber as set forth in claim 19 wherein the heat-resistant concrete comprises.

21. The injection chamber as set forth in claim 19 wherein the interior walls include heat-resistant concrete panels.

22. The injection chamber as set forth in claim 19 wherein the pipes have an inner surface, the inner surface being formed of titanium.

23. The injection chamber as set forth in claim 22 wherein the pipes are formed of titanium.

24. A steam-booster substation for use in an electricity-generating system, the system including a supply of steam, a first generator and a second generator communicating with the steam supply and using the steam to generate electricity, and a supply of super-heated water, the substation comprising:
interior walls;
heat-resistant concrete provided on the interior walls; and
a series of pipes communicating with the super-heated water supply, the substation being positioned between the first and second generators, the substation receiving steam from the first generator, the substation re-heating the steam using the super-heated water in the pipes, the substation feeding the re-heated steam to the second generator.

25. The substation as set forth in claim 24 wherein the heat-resistant concrete comprises detergent.

26. The substation as set forth in claim 24 wherein the interior walls include heat-resistant concrete panels.

27. The substation as set forth in claim 24 wherein the pipes have an inner surface, the inner surface being formed of titanium.

28. The substation as set forth in claim 27 wherein the pipes are formed of titanium.

29. An electricity-generating method comprising the acts of: storing water under pressure in a reservoir;
feeding water through a generator to generate electricity to power the system;
pre-heating water in a solar field;
feeding pre-heated water to an injection chamber including a water chamber and a steam chamber;
converting the pre-heated water to super-heated steam in the steam chamber, the converting act including feeding pre-heated water from the water chamber and feeding super-heated water through pipes in the steam chamber;
feeding super-heated steam to a first steam generator to generate electricity;
re-heating the steam in a steam-booster substation, the reheating act including supplying the steam and super-heated water to the substation;
generating electricity in a second steam generator using re-heated steam from the substation; and
condensing the steam to water in the reservoir.

30. An electricity-generating method comprising the acts of:
providing an injection chamber including interior walls;
providing a steam-booster substation including interior walls, heat-resistant concrete being provided on at least one of the interior walls of the injection chamber and the interior walls of the substation;
feeding pre-heated water to the injection chamber;
converting the pre-heated water to super-heated steam in the injection chamber;
feeding super-heated steam to a first steam generator to generate electricity;
re-heating the steam in the steam-booster substation, the reheating act including supplying the steam to the substation and supplying super-heated water to the substation; and
generating electricity in a second steam generator using re-heated steam from the substation.

31. The method as set forth in claim 30 wherein the providing acts includes the act of mixing detergent with cement to form the heat-resistant concrete.

32. The method as set forth in claim 30 wherein the providing acts include providing heat-resistant concrete on the interior walls of the injection chamber and on the interior walls of the substation.

33. The method as set forth in claim 30 wherein the providing acts include providing heat-resistant concrete panels on the at least one of the interior walls of the injection chamber and the interior walls of the substation.

34. The method as set forth in claim 33 wherein the providing acts include providing heat-resistant concrete panels on the interior walls of the injection chamber and on the interior walls of the substation.

35. The method as set forth in claim 30 wherein the act of providing an injection chamber includes providing an injection chamber including a water chamber and a steam chamber, the steam chamber including the interior walls.

36. The method as set forth in claim 35 wherein the converting act includes feeding pre-heated water from the water chamber and feeding super-heated water to the steam chamber.

37. The method as set forth in claim 36 wherein the act of feeding super-heated steam includes feeding super-heated steam through pipes in the steam chamber.

38. The method as set forth in claim 30 and further comprising the acts of:
storing water under pressure in a reservoir; and
feeding water through a generator to generate electricity to power the system.

39. The method as set forth in claim 38 and further comprising the act of condensing the steam to water in the reservoir.

40. The method as set forth in claim 30 wherein the act of feeding pre-heated water includes pre-heating water in a solar field.

41. The method as set forth in claim 30-wherein the converting act includes feeding super-heated water through pipes in the injection chamber.

42. The method as set forth in claim 41 wherein the act of feeding super-heated water includes super-heating water in a parabolic dish solar array.

43. The method as set forth in claim 42 wherein the act of supplying super-heated water to the substation includes super-heating water in a parabolic dish solar array.

44. A concrete composition comprising:
about one-half part to about one and one-half parts cement;
greater than zero and less than about one part detergent.

45. The concrete composition of claim 44, further comprising about one-half to about one and seven-eighth parts sand.

46. The concrete composition of claim 44, further comprising about one-half part to about one and one-half parts silica sand and about one-eighth part to about three-eighth part fine silica sand.

47. The concrete composition of claim 44, further comprising about one-eighth to about three-eighth parts hardener.

48. The concrete composition of claim 44, further comprising about one-quarter to about three-quarter parts baking soda.

49. The concrete composition of claim 44, wherein the detergent comprises at least one of a nonionic surfactant, an anionic surfactant, a cationic surfactant, a zwitterionic surfactant, an amphoteric surfactant, a semi-polar surfactant and a mixture thereof.

50. The concrete composition of claim 44, wherein the detergent comprises an anionic surfactant.

51. The concrete composition of claim 44, wherein the detergent comprises a non-ionic surfactant.

52. The concrete composition of claim 44, wherein the detergent comprises Liquid All® manufactured by Lever Brothers Company, headquartered in New York, N.Y.

53. The concrete composition of claim 44, wherein the detergent comprises an anionic surfactant and a non-ionic surfactant.

54. The concrete composition of claim 44, wherein the composition can withstand temperatures between 1000 to 2500 degrees Fahrenheit.

55. A heat-resistant concrete composition comprising:
about one-half part to about one and one-half parts cement;
about one-half part to about one and one-half parts silica sand;
about one-eighth part to about three-eighth part fine silica sand;
about one-eighth to about three-eighth part hardener;
about one-quarter to about three-quarter part baking soda; and
greater than zero and less than about one part detergent.

56. The composition of claim 55, wherein the composition can withstand temperatures between 1000 to 2500 degrees Fahrenheit.

57. The concrete composition of claim 55, wherein the detergent comprises at least one of a nonionic surfactant, an anionic surfactant, a cationic surfactant, a zwitterionic surfactant, an amphoteric surfactant, a semi-polar surfactant and mixtures thereof.

58. The concrete composition of claim 55, wherein the detergent comprises an anionic surfactant

59. The concrete composition of claim 55, wherein the detergent comprises a non-ionic surfactant.

60. The concrete composition of claim 55, wherein the detergent comprises Liquid All® manufactured by Lever Brothers Company, headquartered in New York, N.Y.

61. The concrete composition of claim 55, wherein the detergent comprises an anionic surfactant and a non-ionic surfactant.

62. A method of improving the heat-resistance of a concrete composition, the method comprising adding detergent to the concrete composition to form a heat-resistant concrete composition.

63. The method of claim 62, wherein the heat-resistant concrete composition comprises about one-half part to about one and one-half parts cement and greater than zero and less than about one part detergent.

64. The method of claim 62, further comprising adding sand to the concrete composition.

65. The method of claim 64, further comprising hardener to the concrete composition.

66. The concrete composition of claim 64, wherein the sand comprises about one-half part to about one and one-half parts silica sand and about one-eighth part to about three-eighth part fine silica sand.

67. The method of claim 62, further comprising adding about one-half to about one and seven-eighth parts sand to the concrete composition.

68. The method of claim 62, further comprising adding hardener to the concrete composition.

69. The method of claim 62, further comprising adding about one-eighth to about three-eighth parts hardener to the concrete composition.

70. The method of claim 62, further comprising adding baking soda to the concrete composition.

71. The method of claim 62, further comprising adding about one-quarter to about three-quarter parts baking soda to the concrete composition.

72. The method of claim 62, wherein the detergent comprises at least one of a nonionic surfactant, an anionic surfactant, a cationic surfactant, a zwitterionic surfactant, an amphoteric surfactant, a semi-polar surfactant and a mixture thereof.

73. The method of claim 62, wherein the detergent comprises an anionic surfactant.

74. The method of claim 62, wherein the detergent comprises a non-ionic surfactant.

75. The method of claim 62, wherein the detergent comprises Liquid All® manufactured by Lever Brothers Company, headquartered in New York, N.Y.

76. The method of claim 62, wherein the detergent comprises by volume about 65-75% water, about 15-25% anionic surfactant and about 5-10% non-ionic surfactant.

77. The method of claim 62, wherein the detergent comprises an anionic surfactant and a non-ionic surfactant.

78. The method of claim 77, wherein the detergent further comprises monoethanolamine.

79. The method of claim 62, wherein the composition can withstand temperatures between 1000 to 2500 degrees Fahrenheit.

80. A method of manufacturing a concrete composition that can withstand temperatures between 1000 to 2500 degrees Fahrenheit, the method comprising:
mixing an effective amount of detergent with a concrete composition, the amount of detergent being effective to allow the concrete composition to withstand temperatures between 1000 to 2500 degree Fahrenheit.

81. The method of claim 80, wherein the detergent comprises a nonionic surfactant.

82. The method of claim 80, wherein the detergent comprises an anionic surfactant.

83. The method of claim 80, wherein the detergent comprises Liquid All® manufactured by Lever Brothers Company, headquartered in New York, N.Y.

84. The method of claim 80, wherein the detergent comprises an anionic surfactant and a non-ionic surfactant.

85. A method of constructing a structure having improved heat resistance, the method comprising using concrete and detergent to construct the structure, the structure being more resistant to heat than a structure constructed using the same concrete but without the detergent.

86. The method of claim 85, wherein the detergent comprises an anionic surfactant.

87. The method of claim 85, wherein the detergent comprises a non-ionic surfactant.

88. The method of claim 85, wherein the detergent comprises Liquid All® manufactured by Lever Brothers Company, headquartered in New York, N.Y.

89. The method of claim 85, wherein the concrete comprises a heat-resistant aggregate.
